(19) United States
(12) Patent Application Publication
(10) Pub. No.: US 2012/0199173 A1
(43) Pub. Date: Aug. 9, 2012

(54) Interconnection Schemes for Photovoltaic Cells

(75) Inventor: Brian Josef Bartholomeusz, Palo Alto, CA (US)

(73) Assignee: AQT SOLAR, INC., Sunnyvale, CA (US)

(21) Appl. No.: 13/447,066

(22) Filed: Apr. 13, 2012

Related U.S. Application Data
(63) Continuation-in-part of application No. 12/783,412, filed on May 19, 2010.
(60) Provisional application No. 61/230,241, filed on Jul. 31, 2009.

(51) Int. Cl. H01L 31/05; H01L 31/18

(52) U.S. Cl. 136/244; 438/80; 257/E31.113

(57) ABSTRACT

In particular embodiments, a method is described for fabricating a photovoltaic cell and includes providing a substrate; depositing a bottom-contact layer over the substrate; masking a portion of the bottom-contact layer; depositing a photovoltaic-absorber layer over the bottom-contact layer; and depositing a top-contact layer over the a photovoltaic-absorber layer. A portion of the bottom-contact layer is left exposed after depositing the photovoltaic-absorber layer and the top-contact layer as a result of the masking, thereby leaving the exposed portion of the bottom-contact layer suitable for use as an electrical contact.

### RELATED APPLICATIONS

This application is a continuation-in-part under 35 U.S.C. §120 of U.S. patent application Ser. No. 12/783,412, filed 19 May 2010, which claims the benefit under 35 U.S.C. §119(e) of U.S. Provisional Patent Application No. 61/230,241, filed 31 Jul. 2009, which is incorporated herein by reference

### TECHNICAL FIELD

The present disclosure generally relates to photovoltaic devices, and more particularly to interconnection schemes for connecting photovoltaic cells.

### BACKGROUND

Conventional photovoltaic cells, such as crystalline silicon solar cells, are generally inter-connected using a process referred to as “tabbing and stringing” whereby conducting contacts of adjacent photovoltaic cells are electrically connected (tabbed) to form a chain of devices connected in series (the string). A number of these strings are then packaged together to form a module that is installed on rooftops or other power generating locations. In a majority of conventional photovoltaic cells, one of the conducting contacts of each cell is positioned along the bottom surface of a silicon wafer in the form of a metallic layer, which is typically made up of aluminum metal or an aluminum alloy. The top contact of the photovoltaic cell is typically a screen-printed and baked conductive grid formed using a metallic paste, for example. The current collection portion of this grid and the part that is used for inter-connection is generally referred to as the bus-bar. As shown in FIG. 1, individual photovoltaic cells 102 are typically connected by soldering a connection 104, such as a wire for example, between the bus-bar 106 on the top of one cell 102 with the metal surface of the bottom contact 108 at the bottom of the adjacent cell 102.

Not only do these interconnections (e.g., wires) require non-trivial additional space to be left between adjacent photovoltaic cells 102 but the distorted configuration (e.g., bends 110) can result in stresses and fatigue related failure during prolonged usage, particularly if subjected to significant thermal cycling. Additionally, this interconnection process (during module assembly of conventional silicon cells) is laborious and not readily automated. This has resulted in manufacturing inefficiencies and cost contributions.

### BRIEF DESCRIPTION OF THE DRAWINGS

The present disclosure is illustrated for example, and not by way of limitation, in the figures of the accompanying drawings and in which like reference numerals refer to similar elements and in which:

FIG. 1 illustrates a diagrammatic cross-sectional side view of a conventional interconnection arrangement for silicon photovoltaic cells.

FIG. 2 illustrates a diagrammatic cross-sectional side view of an example interconnection arrangement for photovoltaic cells incorporating electrode access contacts.

FIG. 3 illustrates a flowchart illustrating an example method for fabricating photovoltaic cells having electrode access contacts.

FIG. 4 illustrates an example sample holder suitable for use in the method of FIG. 3.

FIG. 5 illustrates a diagrammatic top view of an example chain or string of photovoltaic cells.

FIGS. 6A-6B illustrate a diagrammatic top view of an example chain or string of photovoltaic cells.

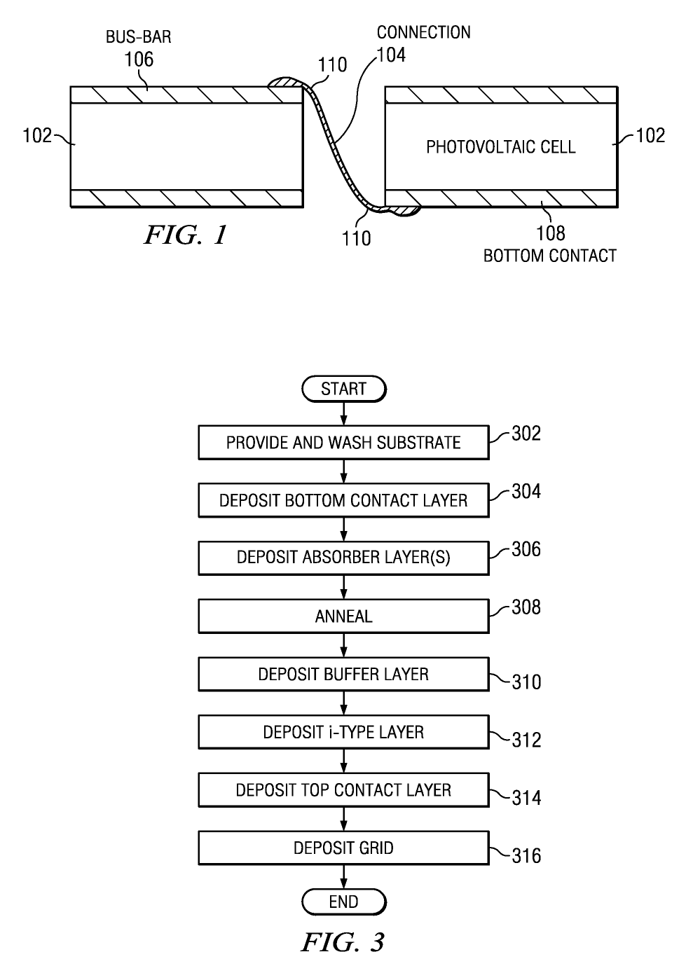

### DESCRIPTION OF EXAMPLE EMBODIMENTS

The present disclosure is now described in detail with reference to a few particular embodiments thereof as illustrated in the accompanying drawings. In the following description, numerous specific details are set forth in order to provide a thorough understanding of the present disclosure. It is apparent, however, to one skilled in the art, that particular embodiments of the present disclosure may be practiced without some or all of these specific details. In other instances, well known process steps and/or structures have not been described in detail in order to not unnecessarily obscure the present disclosure. In addition, while the disclosure is described in conjunction with the particular embodiments, it should be understood that this description is not intended to limit the disclosure to the described embodiments. To the contrary, the description is intended to cover alternatives, modifications, and equivalents as may be included within the spirit and scope of the disclosure as defined by the appended claims.

Particular embodiments relate to the formation, during nominal cell fabrication, of optimally sized and positioned electrode access contacts (EACs) coupled to the top and bottom contacts of, for example, a conventionally shaped and sized thin-film solar or photovoltaic (hereinafter photovoltaic) cell. In particular embodiments, the EACs are located and accessible on the top surface of each photovoltaic cell. Additionally, in particular embodiments, the EACs are distinctly formed such that they are readily identifiable by human or machine vision techniques, and thus can easily be distinguished for interconnection purposes. In various embodiments, the number, size, shape, and position of the EACs may vary according to whatever may be deemed optimal or most desirable for any particular photovoltaic cell.

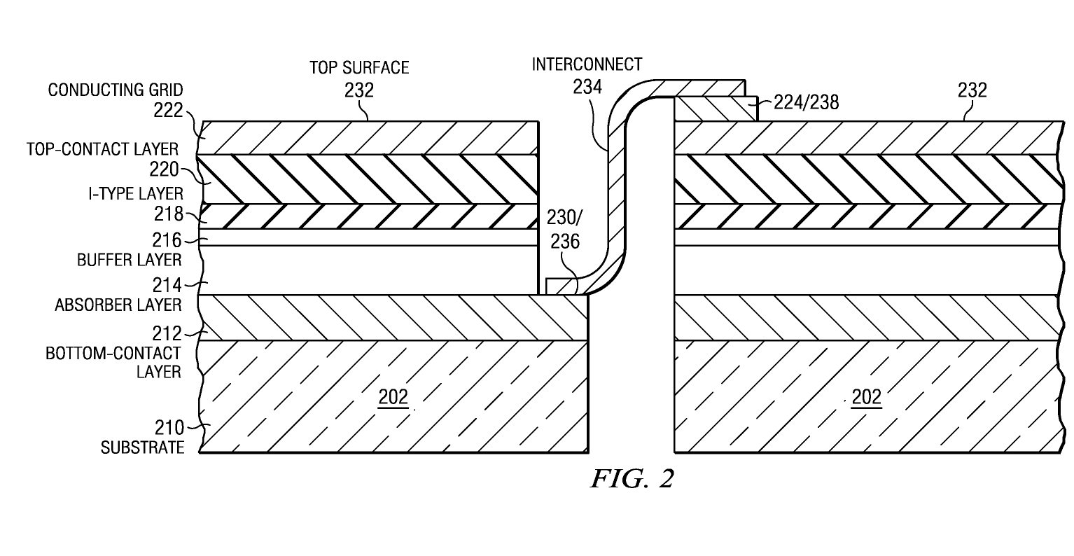

FIG. 2 illustrates a diagrammatic cross-sectional side view of an example interconnection arrangement for photovoltaic cells 202 incorporating EACs 236 and 238. In particular embodiments, photovoltaic cells 202 are thin-film photovoltaic cells. For example, photovoltaic cells 202 may be Copper-Indium-disulfide (“CIS2”) based cells, Copper-Indium-diselenide (“CIS”) based cells, Copper-Indium-Gallium-diselenide (CuInₓGa(₁₋ₓ)Se₂, “CIGS”) based cells, Copper-Zinc-Tin-Sulfur/Selenide (Cu₂ZnSn(S, Se)₄, “CZTS”), or various chalco-pyrite based thin-film photovoltaic cells, among other suitable types of photovoltaic cells. In the illustrated embodiment, each photovoltaic cell 202 comprises a plurality of layers grown or otherwise deposited over a substrate 210. The film stack for a photovoltaic cell 202 may comprise one or more of a substrate 202, a bottom-contact layer 212, an absorber layer 214, a buffer layer 216, an i-type layer 218, a top-contact layer 220, a conducting grid 222, or any combination thereof. In addition, U.S. application Ser. No. 12/953,867, U.S. application Ser. No. 12/016,172, U.S. application Ser. No. 11/923,036, U.S. application Ser. No. 11/923,070, and U.S. application Ser. No. 13/401,512, the text of which are incorporated by reference herein, disclose additional layer arrangements and configurations for photovoltaic cell structures that may be used with particular embodiments disclosed herein.

FIG. 3 illustrates an example method for fabricating one or more photovoltaic cells 202. At step 302, a suitable substrate 210 may be provided and washed with deionized water. At step 304, a conducting bottom-contact layer 212 may be deposited over substrate 210. At step 306, an absorber layer 214 may be deposited over bottom-contact layer 212. At step 308, the film stack may be annealed and cooled. At step 310, a buffer (window) layer 216 may then be deposited over the absorber layer 214. At step 312, an i-type layer 218 may be deposited over the buffer layer 216. At step 314, a top-contact layer 220 may be deposited over the i-type layer 218. At step 316, a conducting grid 222 and bus-bars 224 may be deposited over the top-contact layer 220. Although this disclosure describes and illustrates particular steps of the method of FIG. 3, this disclosure contemplates any suitable steps of the method of FIG. 3. For example, certain steps may be excluded such that the film stack does not include particular layers. Similarly, additional steps may be added or repeated such that the film stack includes additional layers. Furthermore, although this disclosure describes and illustrates particular steps of the method of FIG. 3 as occurring in a particular order, this disclosure contemplates any suitable steps of the method of FIG. 3 occurring in any suitable order. For example, the order of certain steps may be changed such that the particular layers are switched in position in the film stack. Moreover, although this disclosure describes and illustrates particular components, devices, or systems carrying out particular steps of the method of FIG. 3, this disclosure contemplates any suitable combination of any suitable components, devices, or systems carrying out any suitable steps of the method of FIG. 3.

In particular embodiments, the substrate 210 may be any suitable substrate capable of withstanding high temperatures and/or pressures. The substrate 210 may provide structural support for the film stack. For example, the substrate 210 may be soda-lime glass, a metal sheet or foil (e.g., stainless steel, aluminum, tungsten), a semiconductor (e.g., Si, Ge, GaAs), a polymer, another suitable substrate, or any combination thereof, and may have a thickness in the range of approximately 0.7 to 2.3 millimeters (mm), although other thicknesses may be suitable.

In particular embodiments, the substrate 210 may be coated with an electrical contact, such as a bottom-contact layer 212. The bottom-contact layer 212 may be any suitable electrode material, such as, for example, Mo, W, Al, Fe, Cu, Sn, Zn, another suitable electrode material, or any combination thereof, having a thickness in the range of approximately 500 to 2000 nanometers (nm), although other thicknesses may be suitable. If the substrate 210 is a non-transparent material, then the top-contact layer 220 and other layers may be transparent to allow light penetration into the absorber layer 214. In particular embodiments, the substrate 210 may be replaced by another suitable protective layer or coating, or may be added during construction of a solar module or panel. Alternatively, the layers of the photovoltaic cell 202 may be deposited on a flat substrate (such as a glass substrate intended for window installations), or directly on one or more surfaces of a non-imaging solar concentrator, such as a trough-like or Winston optical concentrator.

In particular embodiments, the absorber layer 214 may be a CIS layer, a CIS2 layer, a CIGS layer, a CZTS layer, another suitable photoactive conversion layer, or any combination thereof. The absorber layer 214 may be either a p-type or an n-type semiconductor layer. In some embodiments, absorber layer 214 may actually include a plurality of stacked layers. In particular embodiments, the photovoltaic cell 202 may include multiple absorber layers 214. The plurality of absorber layers 214 or the plurality of stacked layers may vary between, for example, CIS, CIS2, CIGS, CZTS layers. In particular embodiments, absorber layer 214 may have a total thickness in the range of approximately 0.5 to 3 micrometers (μm). Although this disclosure describes particular types of absorber layers 214, this disclosure contemplates any suitable type of absorber layers 214.

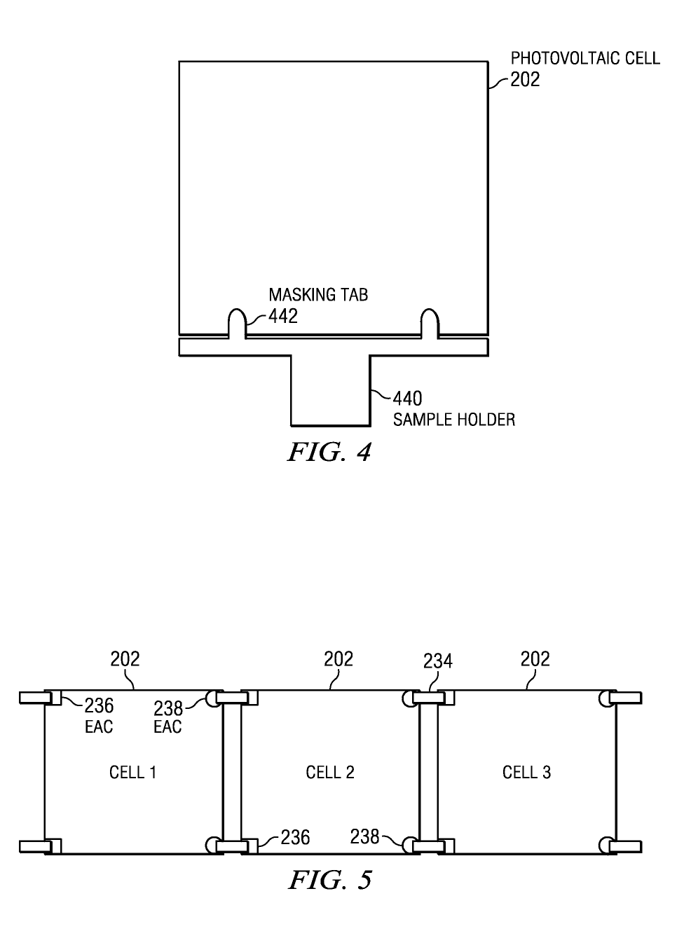

In particular embodiments, while depositing absorber layer 214 and the subsequent layers described below, one or more portions of a peripheral edge of the substrate may be selectively masked such that a portion of the bottom-contact layer 212 may be left exposed. As described below, the exposed portion of the bottom-contact layer 212 serves as the bottom EAC 236 for the photovoltaic cell 202. The masking may be accomplished in a number of ways including relatively more complex ones such as photo-lithography, which is customarily used for semiconductor processing. However one preferred embodiment would utilize specially designed sample holders 440, as illustrated in FIG. 4, in conjunction with appropriate sample rotation or translation to selectively expose or hide the requisite portion of the photovoltaic cell 202 during fabrication. For example, stabilizing protrusions from sample holder 440 may additionally serve to mask selective regions on the sample surface at various stages of the fabrication process. In the case of a CIGS type cell 202 fabricated in a continuous in-line process, after the molybdenum bottom-contact layer 212 has been deposited uniformly over the whole substrate surface, the substrate 210 may be transferred to a sample holder 440 which obscures the EAC regions throughout the subsequent processing.

In particular embodiments, sample holder 440 includes integrally formed (with sample holder 440) masking protrusions or tabs (hereinafter “tabs”) 442. Masking tabs 442 selectively mask desired portions of bottom-contact layer 212 that will subsequently form the bottom EACs 236. Although in the described embodiment, masking tabs 442 integral with the sample holder are used to selectively mask the desired portions of bottom-contact layer 212, it should be appreciated that any suitable means may be used to mask the desired portions of bottom-contact layer 212 to form the bottom EACs 236. In various embodiments, bottom-contact layer 212 may be selectively masked to produce one or more bottom EACs 236 having any desired shape or size (although it may be desirable to maximize the area of the subsequently deposited absorber layer to maximize the light absorbed by the photovoltaic cell 202). For example, in the illustrated embodiment, two bottom EACs 236 will be formed. In an alternate embodiment, an entire peripheral edge of the bottom-contact layer 212 may be masked by a masking tab 442. It should be appreciated that, in this way, the bottom EACs 236 may be formed integrally or concurrently with the conventional fabrication of the photovoltaic cell 202.

Following deposition of the absorber layer 214, the substrate 210, bottom-contact layer 212, and absorber layer 214 may be annealed at step 308 and subsequently cooled. In particular embodiments, a buffer (window) layer 216 may be then grown or otherwise deposited over absorber layer 214 at step 310. Again, buffer layer 216 and the subsequently deposited layers described below are masked by masking tabs 442 thereby leaving portions of the bottom-contact layer 212 exposed to form the bottom EACs 236 of the photovoltaic cell 202. For example, buffer layer 216 may be an n-type semiconducting layer formed from, for example, CdS or In₂S₃, among other suitable materials, and have a thickness in the range of approximately 30 to 70 nm.

In particular embodiments, an i-type layer 218 may be grown or otherwise deposited over buffer layer 216 at step 312. For example, i-type layer 218 may be formed from ZnO and have a thickness in the range of approximately 70 to 100 nm. At step 314, a top-contact layer 220 may then be deposited over the i-type layer 218. In particular embodiment, top-contact layer 220 may be formed from a conducting material such as, for example, AZO (Al₂O₃ doped ZnO), IZO (Indium Zinc Oxide, e.g., 90 wt % In₂O₃/10 wt % ZnO), ITO (Indium Tin Oxide or tin-doped indium oxide, e.g., 90 wt % In₂O₃/10% SnO₂), or any combination thereof, and have a thickness in the range of approximately 0.2 to 1.5 μm.

In particular embodiments, an optional conducting grid 222 including bus-bars 224 (which may be integrally formed with grid 222) may be also deposited at step 316 over the top-contact layer 220. Any of the aforementioned layers may be deposited by any suitable means such as, for example, physical-vapor deposition (PVD), including sputtering or evaporation, chemical-vapor deposition (CVD), electroplating, plasma spraying, printing, solution coating, another suitable deposition process, or any combination thereof, while being held by sample holder 440 and selectively masked by masking tabs 442. Conventional processes such as edge isolation, deposition of an anti-reflective coating, and light soaking, among others, may then follow prior to pre-testing, sorting, packaging, and shipping.

Those of skill in the art will appreciate that FIG. 2 is not to scale as the sum total of the thicknesses of layers 212, 214, 216, 218, 220, 222, and 224 may be, in particular embodiments, still on the order of or less than 1% of the thickness of substrate 210, and thus on the order of or less than 1% of the thickness of the entire photovoltaic cell and may, in some embodiments, be less than one-tenth of 1% of the thickness of the entire photovoltaic cell.

As illustrated in FIG. 2, each photovoltaic cell 202 includes a recessed surface 230 on at least one peripheral edge of the photovoltaic cell (e.g., a side that will neighbor an adjacent photovoltaic cell). However, in particular embodiments and as just described, the recessed surface 230 may only be recessed from an absolute top surface 232 of the photovoltaic cell 202 by approximately 1% of the thickness of the entire photovoltaic cell 202, and may, in some particular embodiments, be recessed from the absolute top surface 232 by less than one-tenth of 1% of the thickness of the entire photovoltaic cell 202. Each exposed recessed surface 230 represents a top surface of the bottom-contact layer 212 and forms and represents the bottom EAC 236 of each photovoltaic cell 202. Thus, for practical purposes, the top surfaces 230 of the bottom EACs 236 are approximately coplanar with the top surface of the top EAC 238 of the adjacent photovoltaic cell 202. In embodiments in which a grid 222 and bus-bars 224 are not deposited, the top EAC 238 may be a portion of the top-contact layer 220 itself or, alternately, a transparent-conductive oxide that may be located at the top-most surface of the cell over the top-contact layer 220. Alternatively, if a top surface metal contact grid 220 is employed, the bus-bar 224 or other portion of the grid 222 may form the top EAC 238 to optimally interface with the bottom EAC 236 of the adjacent cell 202. Again, as described above, the top and bottom EACs may take the form of discrete areas (as shown in FIG. 5 below) or as exposed strips along the cell periphery.

As illustrated in FIG. 2 and FIG. 5, which illustrates a chain or string of electrically connected photovoltaic cells 202. An interconnect 234 electrically connects each bottom EAC 236 of one photovoltaic cell 202 with the top EAC 238 of the immediately adjacent photovoltaic cell 202 and so on to form an electrically connected chain or string of photovoltaic cells 202. For example, the interconnect 234 may be a wire or metallic tab that bridges the gap between the bottom EAC 236 of one cell 202 and the top EAC 238 of the neighboring cell. Due to the flexibility in placement of the contacts 236 and 238, these may be located anywhere on the surface and facilitate non-linear interconnection schemes. Additionally, although the interconnection 234 illustrated in FIG. 2 is shown with two bends, it should be appreciated that this is not to scale and that the bends in the interconnect (if any) will generally not be visible with the naked eye as the bottom EAC 236 of one cell may be virtually coplanar with the top EAC 238 of the neighboring cell. In this way, the interconnect 234 may be significantly less susceptible to stresses as a result of thermal cycling during operation of the photovoltaic cells 202.

Furthermore, in some embodiments, an entire peripheral edge of the bottom-contact layer 212 may be masked by a masking tab 442 such that the bottom EAC 236 extends along most or all of one or more sides of the photovoltaic cell 202. In such an embodiment, a single tab may be used to electrically connect an entire side of the bottom-contact layer 212 of one cell with an entire side (e.g. bus-bar 224) of the adjacent cell. Not only would this interconnection arrangement be even less susceptible to stresses, but it may also provide a physical barrier that seals the space between the adjacent cells. In one embodiment, this sealed space may then be injected or otherwise filled with a filler material.

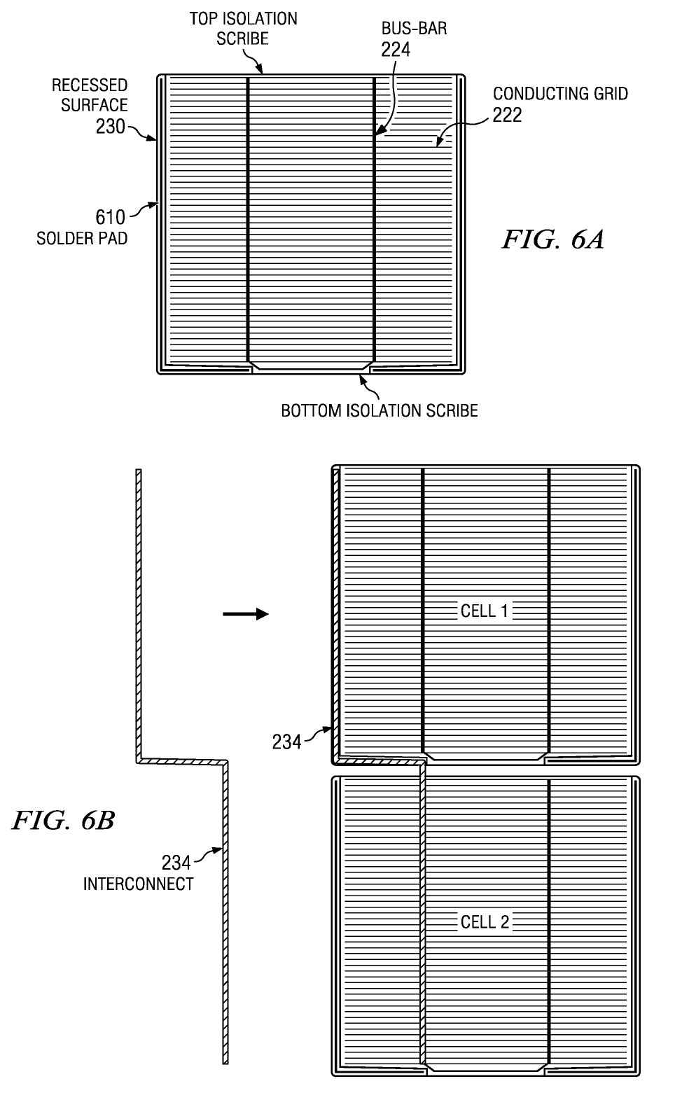

FIGS. 6A-6B illustrate another example of a chain or string of electrically connected photovoltaic cells. FIG. 6A illustrates a diagrammatic top view of an example photovoltaic cell 202, where the bottom-contact layer 212 is exposed on the sides and on portions of the bottom of the photovoltaic cell 202 to create a recessed surface 230 that can function as a EAC 236. The recessed surface 230 may also include a solder pad 610 for facilitating connection of an interconnect 234. The solder pad 610 may be attached to the recessed surface 230 in any suitable manner, such as, for example, by using ultrasonic bonding, conductive epoxy, soldering, another suitable attachment process, or any combination thereof. The photovoltaic cell 202 illustrated in FIG. 6A also includes two bus-bars 224 that may be substantially aligned with the interior edge of the recessed surface 230. Each bus-bar 224 may function as an EAC 238. The bus-bars 224 may be connected to a conducting grid 222, which appears as the grid of horizontal lines across the photovoltaic cell 202 illustrated in FIG. 6A. The top and bottom edges of the photovoltaic cell 202 may include isolation scribes to eliminate short circuits that may exist at the cell periphery. FIG. 6B illustrates a diagrammatic top view of an example of two photovoltaic cells 202 electrically connected to each other with an interconnect 234. An interconnect 234 may be connected to a recessed surface 230/EAC 236 of a first cell and connected to a bus-bar 224/EAC 238 of a second cell, thereby electrically connecting the first cell and second cell. This interconnection scheme may allow the connection of numerous photovoltaic cells 202 in series. The z-shaped interconnect 234 illustrated in FIG. 6B serves to align the top and bottom electrical contacts of adjacent cells and facilitates rapid cell interconnection and module assembly. Although this disclosure describes and illustrated connecting particular photovoltaic cells 202 in a particular manner, this disclosure contemplates connecting any suitable photovoltaic cells 202 in any suitable manner.

The interconnects 234 may be applied with any suitable means including soldering, adhesive bonding, ultrasonic bonding/welding, etc. One advantage of using the EACs described may be that it would be amenable to novel interconnection schemes in which the interconnections 234 are embedded in a top cover material, for example, in some designated pattern. For example, the interconnections 234 may be laid out in a pattern that corresponds to the desired layout of the chain of photovoltaic cells 202. The pattern of interconnects 234 may then be positioned simultaneously over the pattern of photovoltaic cells, or vice versa. In this case all of the photovoltaic cells 202 of a given module may be interconnected in a single-step process through laser-welding, ultrasonic-welding, or another suitable process. As another example, the interconnections 234 may be screen-printed patterns, embedded wires, or strips, which may be pre-coated with a conductive epoxy or low-temperature solder to facilitate adhesion and connectivity with the relevant EACs.

In conclusion, a major advantage of this interconnection scheme would be its ease of automation and the fact that the interconnections 234 themselves would be co-planar and relatively stress-free. The EACs and interconnections 234 would also permit very high packing densities to be achieved due to the absence of connections running over and under adjacent cells.

In particular embodiments, photovoltaic cells 202 may be fabricated on relatively smaller-sized substrates such that they will have the general appearance and dimensions of conventional silicon solar cells (for example, square or pseudo-square 157 mm² or 210 mm² cells), although other arrangements may be suitable. This may facilitate their use as drop-in replacements for equivalent sized and shaped silicon-based cells and, as such, may be compatible with the large global installed base of solar module manufacturers. In particular embodiments, photovoltaic cells 202 may be fabricated in non-standard substrate sizes and shapes. For example, photovoltaic cells 202 may be fabricated in a rectangular louvre configuration that may extend partially or wholly over the width of the resulting module. As another example, one or more substrates 210 may be bonded together to form a monolithic shape equivalent to that of the final module. In this example, the interconnection could be undertaken in a single operation on the monolithically connected cells. This could be via the standard tabbing and stringing process, through screen printing or through the use of a patterned encapsulant.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, this disclosure encompasses any suitable combination of one or more features from any example embodiment with one or more features of any other example embodiment herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

Herein, “or” is inclusive and not exclusive, unless expressly indicated otherwise or indicated otherwise by context. Moreover, “and” is both joint and several, unless expressly indicated otherwise or indicated otherwise by context. Furthermore, “a”, “an,” or “the” is intended to mean “one or more,” unless expressly indicated otherwise or indicated otherwise by context.

What is claimed is:

1. A photovoltaic cell, comprising:
a substrate;
a bottom-contact layer positioned over the substrate, wherein a portion of a top surface of the bottom-contact layer is exposed and electrically connected to a first adjacent cell with a first interconnection;
a photovoltaic-absorber layer positioned over the bottom-contact layer such that the portion of the top surface of the bottom-contact layer remains exposed; and
a top-contact layer positioned over the photovoltaic-absorber layer, wherein a portion of a top surface of the top-contact layer is electrically connected to a second adjacent cell with a second interconnection.

2. The photovoltaic cell of claim 1, wherein the top-contact layer comprises AZO (Al₂O₃ doped ZnO), IZO (Indium Zinc Oxide), or ITO (Indium Tin Oxide or tin-doped indium oxide).

3. The photovoltaic cell of claim 1, wherein the photovoltaic-absorber layer comprises a Copper-Zinc-Tin-Sulfur/Selenide (CZTS) material layer.

4. The photovoltaic cell of claim 1, wherein the photovoltaic-absorber layer comprises a p-type semiconducting layer.

5. The photovoltaic cell of claim 1, wherein the photovoltaic-absorber layer comprises a Copper-Indium-Gallium-Diselenide (CIGS) material layer.

6. The photovoltaic cell of claim 1, wherein the photovoltaic-absorber layer comprises one or more of a Copper-Zinc-Tin-Sulfur/Selenide (CZTS) material layer, a p-type semiconducting layer, or a Copper-Indium-Gallium-Diselenide (CIGS) material layer.

7. The photovoltaic cell of claim 1, further comprising a buffer layer positioned between the photovoltaic-absorber layer and the top-contact layer such that the portion of the top surface of the bottom-contact layer remains exposed.

8. The photovoltaic cell of claim 7, wherein the buffer layer comprises an n-type semiconducting material.

9. The photovoltaic cell of claim 7, further comprising an i-type oxide layer positioned between the buffer layer and the top-contact layer such that the portion of the top surface of the bottom-contact layer remains exposed.

10. The photovoltaic cell of claim 1, further comprising an electrically conductive grid positioned over the top-contact layer such that the portion of the top surface of the bottom-contact layer remains exposed.

11. The photovoltaic cell of claim 1, wherein a combined thickness of the bottom-contact layer, the photovoltaic-absorber layer, the top-contact layer, and any layers between these layers is less than one percent of the thickness of the substrate.

12. A method, comprising:
depositing a bottom-contact layer onto a substrate;
applying a mask to the bottom-contact layer;
depositing a photovoltaic-absorber layer onto the bottom-contact layer, wherein a first portion of a top surface of the bottom-contact layer remains exposed after depositing the photovoltaic-absorber layer;
depositing a top-contact layer onto the photovoltaic-absorber layer, wherein the first portion of the top surface of the bottom-contact layer remains exposed after depositing the top-contact layer; and connecting the first portion of the top surface of the bottom-contact layer to a first adjacent cell with a first interconnection.

13. The method of claim 12, wherein applying the mask to the bottom-contact layer comprises using photolithography to selectively remove one or more portions of the photovoltaic-absorber layer and the top-contact layer and any layers therebetween, such that the first portion of the top surface of the bottom-contact layer is exposed.

14. The method of claim 12, wherein applying the mask to the bottom-contact layer comprises using a sample holder that comprises a protrusion that covers a portion of the bottom-contact layer during the deposition of the photovoltaic-absorber layer and the top-contact layer and any layers therebetween, such that the first portion of the top surface of the bottom-contact layer is exposed.

15. The method of claim 12, further comprising annealing the substrate, the bottom-contact layer, and the photovoltaic layer after deposition of the photovoltaic-absorber layer and prior to deposition of the top-contact layer.

16. The method of claim 12, further comprising depositing a buffer layer onto the photovoltaic-absorber layer and under the top-contact layer, wherein the first top portion of the top surface of the bottom contact layer is exposed after deposition the buffer layer.

17. The method of claim 16, wherein the buffer layer comprises an n-type semiconducting material.

18. The method of claim 16, further comprising depositing an i-type oxide layer onto the buffer layer and under the top-contact layer, wherein the first top portion of the top surface of the bottom contact layer is exposed after deposition the i-type oxide layer.

19. The method of claim 12, further comprising depositing an electrically conductive grid onto the top-contact layer.

20. The method of claim 12, wherein the top-contact layer comprises AZO (Al₂O₃ doped ZnO), IZO (Indium Zinc Oxide), or ITO (Indium Tin Oxide or tin-doped indium oxide).

21. The method of claim 12, wherein the photovoltaic-absorber layer comprises a Copper-Zinc-Tin-Sulfur/Selenide (CZTS) material layer.

22. The method of claim 12, wherein the photovoltaic-absorber layer comprises a p-type semiconducting layer.

23. The method of claim 12, wherein the photovoltaic-absorber layer comprises a Copper-Indium-Gallium-Diselenide (CIGS) material layer.

24. The method of claim 12, wherein the photovoltaic-absorber layer comprises one or more of a Copper-Zinc-Tin-Sulfur/Selenide (CZTS) material layer, a p-type semiconducting layer, or a Copper-Indium-Gallium-Diselenide (CIGS) material layer.
